(19) United States
(12) Patent Application Publication
(10) Pub. No.: US 2018/0240877 A1
(43) Pub. Date: Aug. 23, 2018

(54) TRANSISTOR

(71) Applicant: Nuvoton Technology Corporation, Hsinchu (TW)

(72) Inventors: Jung-Tse Tsai, Hsinchu (TW); Heng-Kuang Lin, Hsinchu (TW)

(73) Assignee: Nuvoton Technology Corporation, Hsinchu (TW)

(21) Appl. No.: 15/866,423

(22) Filed: Jan. 9, 2018

(30) Foreign Application Priority Data
Feb. 20, 2017 (TW) 106105541

(51) Int. Cl. H01L 29/15; H01L 29/10; H01L 29/66; H01L 29/778; H01L 21/02

(52) U.S. Cl. CPC H01L 29/155; H01L 29/1075; H01L 29/66462; H01L 29/2003; H01L 21/02507; H01L 21/02241; H01L 29/7783

(57) ABSTRACT

A transistor including a buffer layer, a channel layer, a barrier layer, a superlattice structure, a gate, a source and a drain is provided. The buffer layer, the channel layer, the barrier layer, the superlattice structure and the gate are sequentially disposed on a substrate. The source and drain are disposed on the barrier layer and respectively at two sides of the superlattice structure, or on the channel layer and respectively at two sides of the barrier layer. The superlattice structure includes at least one first metal nitride layer and at least one second metal nitride layer stacked to each other. The average lattice constant of the superlattice structure is greater than that of GaN. The metal of each of the first and second metal nitride layers is at least one selected from the group consisting of Al, Ga and In. The first and second metal nitride layers are different.

### CROSS-REFERENCE TO RELATED APPLICATION

This application claims the priority benefit of Taiwan application serial no. 106105541, filed on Feb. 20, 2017. The entirety of the above-mentioned patent application is hereby incorporated by reference herein and made a part of this specification.

### BACKGROUND OF THE INVENTION

### Field of the Invention

The invention relates to a semiconductor device, and particularly relates to a transistor.

### Description of Related Art

For a GaN-based transistor, since its advantages of high electron mobility, high voltage resistance, low channel resistance and fast switching, it has been gradually applied to power devices. In a nitride material containing Group III elements, due to the uneven distribution of electrons, a spontaneous polarization field will be generated on a c-axis. Additionally, between heterogeneous materials, energy band discontinuity and lattice constant mismatch will generate a piezoelectric polarization field. Thus, electrons are confined to a triangle potential well to form a two-dimensional electron gas with high electron concentration.

Although the two-dimensional electron gas with high electron concentration and excellent transmission characteristics make the performance of output current density and on-resistance of the device extremely excellent, it causes the device to be in a normally on state, and a normally off (or enhancement mode) electronic device is not easily manufactured, resulting in many restrictions in the application.

To be easy to use in the application, how to develop a GaN field effect transistor with a threshold voltage (Vth) greater than 0 volt is very important. At present, the mainstream technology includes the use of a recessed gate, a fluoride ion processed gate, or a p-(Al)GaN epitaxial layer gate. Additionally, a nitride depolarization layer containing Group III elements may also be used. However, for the use of the recessed gate, the fluoride ion processed gate and the thin InGaN depolarization layer, the threshold voltage thereof is still relatively unstable or still less than +1 volt. Additionally, at present, (Al)GaN is mostly used as the mainstream technology. However, in addition to the epitaxial growth is difficult, the increase of the threshold voltage is also quite limited.

### SUMMARY OF THE INVENTION

The invention provides a transistor, of which a gate and a barrier layer having a superlattice structure therebetween.

The invention provides a transistor including a buffer layer, a channel layer, a barrier layer, a superlattice structure, a gate, a source and a drain. The buffer layer is disposed on a substrate. The channel layer is disposed on the buffer layer. The barrier layer is disposed on the channel layer. The superlattice structure is disposed on the barrier layer. The gate is disposed on the superlattice structure. The source is disposed on the barrier layer and located at one side of the superlattice structure, or disposed on the channel layer and located at one side of the barrier layer. The drain is disposed on the barrier layer and located at another side of the superlattice structure, or disposed on the channel layer and located at another side of the barrier layer. The superlattice structure includes at least one first metal nitride layer and at least one second metal nitride layer stacked to each other, and the average lattice constant of the superlattice structure is greater than the lattice constant of GaN. The metal of each of the first metal nitride layer and the second metal nitride layer is at least one selected from the group consisting of Al, Ga and In. The first metal nitride layer and the second metal nitride layer are different from each other.

According to an embodiment of the invention, a thickness of the superlattice structure is not more than 200 nm, for example.

According to an embodiment of the invention, a thickness of the first metal nitride layer is between 0.2 nm and 50 nm, for example.

According to an embodiment of the invention, a thickness of the second metal nitride layer is between 0.2 nm and 50 nm, for example.

According to an embodiment of the invention, the at least one first metal nitride layer is a plurality of the first metal nitride layers, for example. The at least one second metal nitride layer is a plurality of the second metal nitride layers, for example. The at least one first metal nitride layer and the at least one second metal nitride layer are alternatively stacked to each other.

According to an embodiment of the invention, the superlattice structure further includes at least one third metal nitride layer. The at least one first metal nitride layer, the at least one second metal nitride layer and the at least one third metal nitride layer are stacked to each other.

According to an embodiment of the invention, a thickness of the third metal nitride layer is between 0.2 nm and 50 nm, for example.

According to an embodiment of the invention, the at least one first metal nitride layer is a plurality of the first metal nitride layers, for example. The at least one second metal nitride layer is a plurality of the second metal nitride layers, for example. The at least one third metal nitride layer is a plurality of the third metal nitride layers, for example. The at least one first metal nitride layer, the at least one second metal nitride layer and the at least one third metal nitride layer are alternatively stacked to each other.

According to an embodiment of the invention, each of the first metal nitride layers has the same thickness, for example.

According to an embodiment of the invention, each of the first metal nitride layers has different thickness, for example.

According to an embodiment of the invention, each of the second metal nitride layers has the same thickness, for example.

According to an embodiment of the invention, each of the second metal nitride layers has different thickness, for example.

According to an embodiment of the invention, each of the third metal nitride layers has the same thickness, for example.

According to an embodiment of the invention, each of the third metal nitride layers has different thickness, for example.

According to an embodiment of the invention, a material of the barrier layer is AlGaN, AlInN, InGaN, or AlInGaN, for example.

According to an embodiment of the invention, a material of the channel layer is GaN, for example.

Based on the above, in the transistor of the invention, the superlattice structure is disposed between the gate and the barrier layer, and the average lattice constant of the superlattice structure is greater than the lattice constant of GaN. Therefore, the transistor of the invention can be formed a normally off transistor by the superlattice structure depleting the two-dimensional electron gas formed in the barrier layer, and thus the problem that the threshold voltage is too low can be improved.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view illustrating a transistor according to an embodiment of the invention.

FIG. 2 is a schematic cross-sectional view illustrating a transistor according to another embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

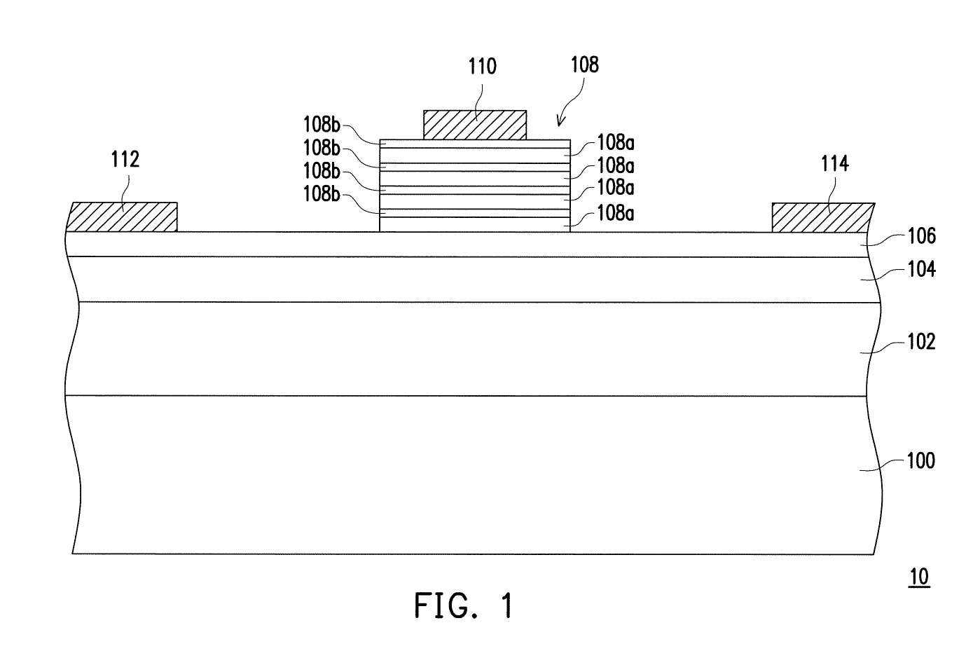

FIG. 1 is a schematic cross-sectional view illustrating a transistor according to an embodiment of the invention. Referring to FIG. 1, a transistor 10 includes a buffer layer 102, a channel layer 104, a barrier layer 106, a superlattice structure 108, a gate 110, a source 112 and a drain 114. In the embodiment, the superlattice structure 108 having a depolarization field is used to deplete the two-dimensional electron gas formed in the barrier layer 106, so as to form a normally off transistor. Additionally, by changing the thickness and composition of each layer in the superlattice structure 108, the intensity of the depolarization field can be controlled so as to improve the problem that the threshold voltage is too low. Each component is further illustrated below.

The buffer layer 102 is disposed on a substrate 100. The substrate 100 is a silicon substrate, a SiC substrate, a sapphire substrate, or a GaN substrate, for example. A material of the buffer layer 102 is GaN, AlGaN, or AlN, for example. Additionally, the buffer layer 102 may be doped with C or Fe to increase the resistance value. The channel layer 104 is disposed on the buffer layer 102. A material of the channel layer 104 is GaN, for example, and a thickness thereof is between 100 nm and 1000 nm, for example. The barrier layer 106 is disposed on the channel layer 104. The barrier layer 106 may be a ternary Group III metal nitride layer or a quaternary Group III metal nitride layer. A material of the ternary Group III metal nitride layer may be AlInN, InGaN, or AlGaN. A material of the quaternary Group III metal nitride layer may be AlInGaN. A thickness of the barrier layer 106 is between 5 nm and 80 nm, for example. The superlattice structure 108 is disposed on the barrier layer 106. The gate 110 is disposed on the superlattice structure 108. A material of the gate 110 is metal, for example. The source 112 and the drain 114 are disposed on the barrier layer 106 and respectively located at two sides of the superlattice structure 108. Alternatively, in another embodiment, the source 112 and the drain 114 may also be disposed on the channel layer 104 and respectively located at two sides of the barrier layer 106. In the embodiment, the source 112 and the drain 114 are respectively separated from the superlattice structure 108 by a predetermined distance.

In the embodiment, the superlattice structure 108 is composed of metal nitride layers 108a and metal nitride layers 108b stacked to each other, and the average lattice constant of the superlattice structure 108 is greater than the lattice constant of GaN. A thickness of the superlattice structure 108 is not more than 200 nm. Specifically, in the embodiment, the superlattice structure 108 is composed of four-layer metal nitride layers 108a and four-layer metal nitride layers 108b alternatively stacked to each other, but the invention is not limited thereto. In other embodiments, the superlattice structure 108 may also be composed of more or fewer layers of the metal nitride layers 108a and more or fewer layers of the metal nitride layers 108b alternatively stacked to each other, as long as the thickness of the formed superlattice structure 108 is not more than 200 nm and the average lattice constant of the superlattice structure 108 is greater than the lattice constant of GaN.

In the superlattice structure 108, a thickness of the metal nitride layer 108a is between 0.2 nm and 50 nm, for example, and a thickness of the metal nitride layer 108b is between 0.2 nm and 50 nm, for example. In the embodiment, the thickness of the metal nitride layer 108a is different from the thickness of the metal nitride layer 108b, and the thicknesses thereof are respectively 7 nm and 1 nm, but the invention is not limited thereto. In other embodiments, the thickness of the metal nitride layer 108a may also be the same as the thickness of the metal nitride layer 108b. Additionally, in the embodiment, each of the metal nitride layers 108a has the same thickness, and each of the metal nitride layers 108b has the same thickness, but the invention is not limited thereto. In other embodiments, each of the metal nitride layers 108a may have different thickness, and each of the metal nitride layers 108b may have different thickness. Additionally, in the embodiment, each of metal nitride stacks (composed of one-layer metal nitride layer 108a and one-layer metal nitride layer 108b) has the same thickness, but the invention is not limited thereto. In other embodiments, each of the metal nitride stacks may have different thickness. Furthermore, in the embodiment, the metal nitride layer 108a is in contact with the barrier layer 106, but the invention is not limited thereto. In other embodiments, it is possible that the metal nitride layer 108b is in contact with the barrier layer 106.

The metal of each of the metal nitride layer 108a and the metal nitride layer 108b is at least one selected from the group consisting of Al, Ga and In, and the condition thereof is that the material of the metal nitride layer 108a is different from that of the metal nitride layer 108b. In other words, overall, the superlattice structure 108 composed of the metal nitride layer 108a and the metal nitride layer 108b may be a ternary Group III metal nitride structure or a quaternary Group III metal nitride structure.

In the condition that the superlattice structure 108 is the ternary Group III metal nitride structure, the metal nitride layer 108a and the metal nitride layer 108b meet any of the following conditions:

(1) One of the metal nitride layer 108a and the metal nitride layer 108b includes ternary Group III metal nitride, and another includes binary Group III metal nitride. The ternary Group III metal nitride may be AlGaN, AlInN, or InGaN. The binary Group III metal nitride may be AlN, InN, or GaN.
(2) Both the metal nitride layer 108a and the metal nitride layer 108b include binary Group III metal nitride.
(3) Both the metal nitride layer 108a and the metal nitride layer 108b include ternary Group III metal nitride. At this time, the composition ratio of the ternary Group III metal nitride in the metal nitride layer 108a is different from that of the ternary Group III metal nitride in the metal nitride layer 108b.

In the condition that the superlattice structure 108 is the quaternary Group III metal nitride structure, the metal nitride layer 108a and the metal nitride layer 108b meet any of the following conditions:

(1) Both the metal nitride layer 108a and the metal nitride layer 108b include ternary Group III metal nitride.
(2) One of the metal nitride layer 108a and the metal nitride layer 108b includes ternary Group III metal nitride, and another includes binary Group III metal nitride.

In the transistor 10 of the invention, the structure of the superlattice structure 108 is not particularly limited. That is, the stacking order, the material, the number of layers and the thickness of each of the metal nitride layer 108a and the metal nitride layer 108b are not limited, as long as the thickness of the formed superlattice structure 108 is not more than 200 nm and the average lattice constant of the superlattice structure 108 is greater than the lattice constant of GaN. Therefore, the transistor 10 of the invention can be formed the normally off transistor by the superlattice structure 108 depleting the two-dimensional electron gas formed in the barrier layer 106, and thus the problem that the threshold voltage is too low can be improved.

In the embodiment, the superlattice structure 108 is composed of the metal nitride layers 108a and the metal nitride layers 108b stacked to each other, but the invention is not limited thereto. In other embodiments, the superlattice structure may further include a metal nitride layer other than the metal nitride layer 108a and the metal nitride layer 108b and is composed of the three metal nitride layers stacked to each other.

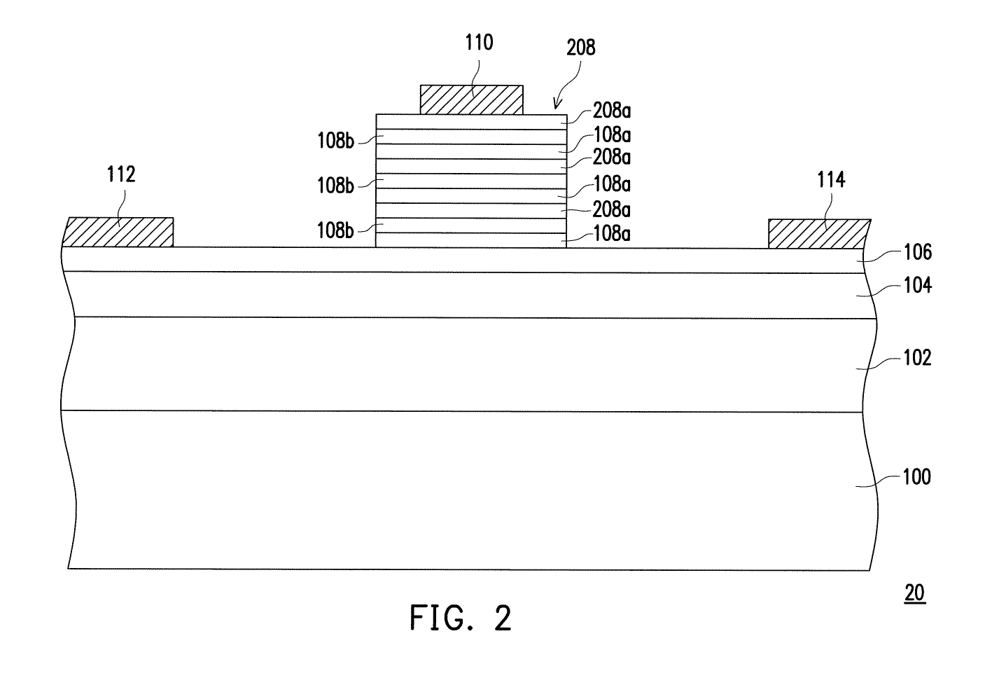

FIG. 2 is a schematic cross-sectional view illustrating a transistor according to another embodiment of the invention. In the embodiment, the identical components as FIG. 1 will be denoted by the identical reference numerals, and repeated description is omitted.

Referring to FIG. 2, the difference between a transistor 20 and the transistor 10 is that, in the transistor 20, a superlattice structure 208 not only includes the metal nitride layer 108a and metal nitride layer 108b, but also includes a metal nitride layer 208a. This will be further illustrated below.

The superlattice structure 208 is composed of the metal nitride layers 108a, the metal nitride layers 108b and the metal nitride layers 208a stacked to each other, and the average lattice constant of the superlattice structure 208 is greater than the lattice constant of GaN. A thickness of the superlattice structure 208 is not more than 200 nm. In the embodiment, the superlattice structure 208 is composed of three-layer metal nitride layers 108a, three-layer metal nitride layers 108b and the metal nitride layer 208a alternatively stacked to each other, but the invention is not limited thereto. In other embodiments, the superlattice structure 208 may also be composed of more or fewer layers of the metal nitride layers 108a, more or fewer layers of the metal nitride layers 108b and more or fewer layers of the metal nitride layers 208a alternatively stacked to each other, as long as the thickness of the formed superlattice structure 208 is not more than 200 nm and the average lattice constant of the superlattice structure 208 is greater than the lattice constant of GaN.

Additionally, as the transistor 10, in the transistor 20, the thickness of each of the metal nitride layers 108a, the metal nitride layers 108b and the metal nitride layers 208a are not limited, as long as the thickness of the formed superlattice structure 208 is not more than 200 nm and the average lattice constant of the superlattice structure 208 is greater than the lattice constant of GaN.

Additionally, in the embodiment, the metal nitride layer 108a is in contact with the barrier layer 106, but the invention is not limited thereto. In other embodiments, it is possible that the metal nitride layer 108b or the metal nitride layer 208b is in contact with the barrier layer 106.

As the metal nitride layer 108a and the metal nitride layer 108b, the metal of the metal nitride layer 208a is at least one selected from the group consisting of Al, Ga and In, and the condition thereof is that the materials of the metal nitride layer 108a, the metal nitride layer 108b and the metal nitride layer 208a are different. That is, overall, the superlattice structure 208 composed of the metal nitride layer 108a, the metal nitride layer 108b and the metal nitride layer 208a is a quaternary Group III metal nitride structure, and the metal nitride layer 108a, the metal nitride layer 108b and the metal nitride layer 208a meet any of the following conditions:

(1) One of the metal nitride layer 108a, the metal nitride layer 108b and the metal nitride layer 208a includes quaternary Group III metal nitride, and the rest both include ternary Group III metal nitride. The quaternary Group III metal nitride layer is AlInGaN.
(2) One of the metal nitride layer 108a, the metal nitride layer 108b and the metal nitride layer 208a includes quaternary Group III metal nitride, and the rest both include binary Group III metal nitride.
(3) One of the metal nitride layer 108a, the metal nitride layer 108b and the metal nitride layer 208a includes quaternary Group III metal nitride, one of the rest includes ternary Group III metal nitride, and another of the rest includes binary Group III metal nitride.
(4) All the metal nitride layer 108a, the metal nitride layer 108b and the metal nitride layer 208a include ternary Group III metal nitride.
(5) Two of the metal nitride layer 108a, the metal nitride layer 108b and the metal nitride layer 208a include ternary Group III metal nitride, and the rest includes binary Group III metal nitride.
(6) One of the metal nitride layer 108a, the metal nitride layer 108b and the metal nitride layer 208a includes ternary Group III metal nitride, and the rest both include binary Group III metal nitride.
(7) All the metal nitride layer 108a, the metal nitride layer 108b and the metal nitride layer 208a include binary Group III metal nitride.

In the transistor 20 of the invention, the structure of the superlattice structure 208 is not particularly limited. That is, the stacking order, the material, the number of layers and the thickness of each of the metal nitride layer 108a, the metal nitride layer 108b and the metal nitride layer 208a are not limited, as long as the thickness of the formed superlattice structure 208 is not more than 200 nm and the average lattice constant of the superlattice structure 208 is greater than the lattice constant of GaN. Therefore, the transistor 20 of the invention can be formed the normally off transistor by the superlattice structure 208 depleting the two-dimensional electron gas formed in the barrier layer 106, and thus the problem that the threshold voltage is too low can be improved.

Certainly, in other embodiments, the superlattice structure may include additional metal nitride layers other than the metal nitride layer 108a, the metal nitride layer 108b and the metal nitride layer 208a, as long as the additional metal nitride layers meet the aforementioned conditions. That is, in this case, the stacking order, the material, the number of layers and the thickness of each of the metal nitride layers are not limited, as long as the thickness of the formed superlattice structure is not more than 200 nm and the average lattice constant of the superlattice structure is greater than the lattice constant of GaN.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A transistor, comprising:
a buffer layer, disposed on a substrate;
a channel layer, disposed on the buffer layer;
a barrier layer, disposed on the channel layer;
a superlattice structure, disposed on the barrier layer, the superlattice structure comprising at least one first metal nitride layer and at least one second metal nitride layer stacked to each other, and an average lattice constant of the superlattice structure being greater than a lattice constant of GaN, wherein the metal of each of the first metal nitride layer and the second metal nitride layer is at least one selected from the group consisting of Al, Ga and In, and the first metal nitride layer and the second metal nitride layer are different from each other;
a gate, disposed on the superlattice structure; and
a source, disposed on the barrier layer and located at one side of the superlattice structure, or disposed on the channel layer and located at one side of the barrier layer; and
a drain, disposed on the barrier layer and located at another side of the superlattice structure, or disposed on the channel layer and located at another side of the barrier layer.

2. The transistor according to claim 1, wherein a thickness of the superlattice structure is not more than 200 nm.

3. The transistor according to claim 1, wherein a thickness of the first metal nitride layer is between 0.2 nm and 50 nm.

4. The transistor according to claim 1, wherein a thickness of the second metal nitride layer is between 0.2 nm and 50 nm.

5. The transistor according to claim 1, wherein the at least one first metal nitride layer comprises a plurality of the first metal nitride layers, the at least one second metal nitride layer comprises a plurality of the second metal nitride layers, and the at least one first metal nitride layer and the at least one second metal nitride layer are alternatively stacked to each other.

6. The transistor according to claim 5, wherein each of the first metal nitride layers has the same thickness.

7. The transistor according to claim 5, wherein each of the first metal nitride layers has different thickness.

8. The transistor according to claim 5, wherein each of the second metal nitride layers has the same thickness.

9. The transistor according to claim 5, wherein each of the second metal nitride layers has different thickness.

10. The transistor according to claim 1, wherein the superlattice structure further comprises at least one third metal nitride layer, and the at least one first metal nitride layer, the at least one second metal nitride layer and the at least one third metal nitride layer are stacked to each other.

11. The transistor according to claim 10, wherein a thickness of the third metal nitride layer is between 0.2 nm and 50 nm.

12. The transistor according to claim 10, wherein the at least one first metal nitride layer comprises a plurality of the first metal nitride layers, the at least one second metal nitride layer comprises a plurality of the second metal nitride layers, the at least one third metal nitride layer comprises a plurality of the third metal nitride layers, and the at least one first metal nitride layer, the at least one second metal nitride layer and the at least one third metal nitride layer are alternatively stacked to each other.

13. The transistor according to claim 12, wherein each of the first metal nitride layers has the same thickness.

14. The transistor according to claim 12, wherein each of the first metal nitride layers has different thickness.

15. The transistor according to claim 12, wherein each of the second metal nitride layers has the same thickness.

16. The transistor according to claim 12, wherein each of the second metal nitride layers has different thickness.

17. The transistor according to claim 12, wherein each of the third metal nitride layers has the same thickness.

18. The transistor according to claim 12, wherein each of the third metal nitride layers has different thickness.

19. The transistor according to claim 1, wherein a material of the barrier layer comprises AlGaN, AlInN, InGaN, or AlInGaN.

20. The transistor according to claim 1, wherein a material of the channel layer comprises GaN.
